(19) United States
(12) Patent Application Publication
(10) Pub. No.: US 2014/0103449 A1
(43) Pub. Date: Apr. 17, 2014

(54) OXYGEN FREE RTA ON GATE FIRST HKMG STACKS

(71) Applicants: Jan HOENTSCHEL, Dresden (DE); Shiang Yang Ong, Dresden (DE); Ran Yan, Dresden (DE)

(72) Inventors: Jan HOENTSCHEL, Dresden (DE); Shiang Yang Ong, Dresden (DE); Ran Yan, Dresden (DE)

(73) Assignee: GlobalFoundries Singapore Pte. Ltd., Singapore (SG)

(21) Appl. No.: 13/649,858

(22) Filed: Oct. 11, 2012

(51) Int. Cl. H01L 29/78; H01L 21/336

(52) U.S. Cl. 257/401; 438/294; 257/E21.409; 257/E29.255

(57) ABSTRACT

A method of fabricating a semiconductor device with improved Vt and the resulting device are disclosed. Embodiments include forming an HKMG stack on a substrate; implanting dopants in active regions of the substrate; and performing an RTA in an environment of nitrogen and no more than 30% oxygen.

### TECHNICAL FIELD

The present disclosure relates to fabrication of high-k/metal gate (HKMG) stacks for semiconductors. The disclosure is particularly applicable to fabrication of low power, high performance semiconductors in 32 nanometer (nm) technology nodes and beyond.

### BACKGROUND

A gate first process for forming HKMG stacks has become an industry standard for CMOS technologies. Gate first refers to the formation of a gate electrode prior to source/drain implantation. For example, as illustrated in FIGS. 1A and 1B, shallow trench isolation (STI) regions are formed in a silicon substrate 103. Next, a high-k dielectric layer 105, which may, for example, be formed of hafnium oxide (HfO₂) or hafnium silicon oxynitride (HfSiON), a metal electrode layer 107, for example, of titanium nitride (TiN), an amorphous silicon (a-Si) or polysilicon (poly-Si) layer 109, and a gate capping layer 111 are sequentially formed on the substrate 103. Adverting to FIG. 1B, the layers are patterned by lithography and etching to form a gate electrode structure 113, and spacers 115 are formed on opposite sides of gate electrode structure 113. Source/drain regions are then doped, using the gate electrode and spacers as a mask, and heated, for example by a rapid thermal anneal (RTA) in a nitrogen and oxygen (N₂O₂) atmosphere, to activate the dopants.

During this process, however, the edge of the interface between the silicon (Si) channel (in the silicon substrate under gate electrode structure 113) and the HKMG becomes sensitive to oxygen (O₂) accumulation, particularly for NFET devices. This changes the charging at the work function, especially along the edges of the gate, since the poly-Si line follows the topography of STI divots at the interface between the active Si substrate islands and the STI corners in a standard device. Due to the incorporation of O₂, the charging changes and the work function shifts, which results in an increase in device threshold voltage Vt. As the dimensions of transistors continue to shrink, and the device width decreases, Vt increases even more. See, for example, graph 201 in FIG. 2, which shows increase in threshold voltage with decreasing transistor width. This effect, known as the linear threshold voltage (Vt_{Lin}) versus width effect, adversely affects NFETs in particular.

A need therefore exists for methodology for processing HKMG stacks with reduced incorporation of O₂ after the HKMG stack is formed.

### SUMMARY

An aspect of the present disclosure is a method of fabricating a semiconductor device with reduced O₂ incorporation after gate stack formation.

Another aspect of the present disclosure is a semiconductor device formed with reduced O₂ incorporation after gate stack formation.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method comprising: forming a high-k/metal gate (HKMG) stack on a substrate; implanting dopants in active regions of the substrate; and performing a rapid thermal anneal (RTA) in an environment of nitrogen and no more than 30% oxygen.

Aspects of the present disclosure include performing the RTA in an oxygen free environment. Further aspects include performing the RTA at a temperature of 1035° C. to 1075° C. Other aspects include implanting n-type dopants in the active regions of the substrate. Another aspect include forming the HKMG stack by: forming a high-k dielectric layer on the substrate; forming a metal electrode layer on the high-k dielectric layer; forming an amorphous silicon (a-Si) or polycrystalline silicon (poly-Si) layer on the metal electrode layer; and patterning the layers. Additional aspects include forming the high-k dielectric layer of a hafnium oxide (HfO₂) or hafnium silicon oxynitride (HfSiON). Further aspects include patterning by lithographic etching. Other aspects include forming spacers on opposite sides of the HKMG stack prior to implanting dopants in the active regions of the substrate. An additional aspect includes forming shallow trench isolation (STI) regions in the substrate prior to forming the HKMG stack.

Another aspect of the present disclosure is a device including: a substrate; a high-k/metal gate (HKMG) stack on the substrate; source/drain regions in the substrate on opposite sides of the HKMG stack; a dopant implanted in the source/drain regions and activated with a rapid thermal anneal (RTA) in an environment of nitrogen and no more than 30% oxygen.

Aspects include the dopant is activated with an RTA in an oxygen free environment. Further aspects include the dopant being an n-type dopant. Other aspects include the HKMG including: a high-k dielectric layer on the substrate; a metal electrode layer on the high-k dielectric layer; and an a-Si or poly-Si layer on the metal electrode layer. Another aspect includes STI regions in the substrate adjacent the source/drain regions. An additional aspect includes spacers at opposite sides of the HKMG stack.

Another aspect of the present disclosure is a method including forming shallow trench isolation (STI) regions in a substrate; forming a high-k/metal gate (HKMG) stack on the substrate between two adjacent STI regions, the HKMG stack comprising: a high-k dielectric layer on the substrate, a metal electrode layer on the high-k dielectric layer, and an amorphous silicon (a-Si) or polycrystalline silicon (poly-Si) layer on the metal electrode layer; implanting n-type dopants in source/drain regions of the substrate between the two STI regions, at opposite sides of the HKMG stack; and performing a rapid thermal anneal (RTA) in an environment of nitrogen and no more than 30% oxygen.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B schematically illustrate a gate first process flow for fabricating an HKMG;

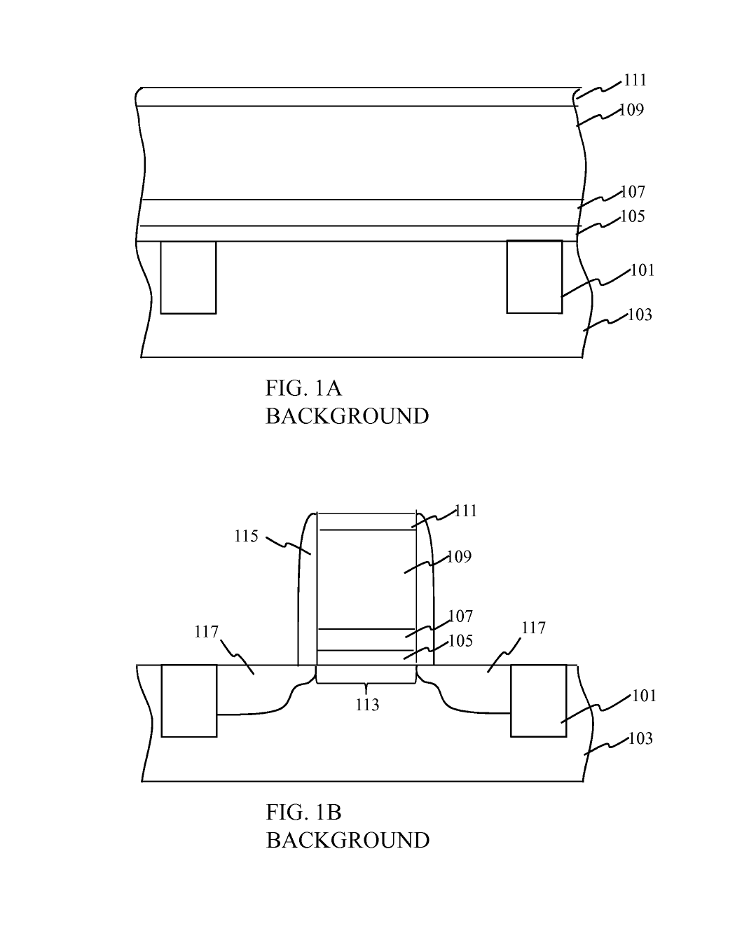

FIG. 2 schematically illustrates a graph of the Vt_{Lin} versus width effect; and

FIG. 3 is a flowchart illustrating a process flow, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of oxygen accumulation resulting in increased device threshold voltage Vt attendant upon thermal annealing during formation of HKMGs, particularly NFET HKMGs, by gate first processes. In accordance with embodiments of the present disclosure, after an HKMG stack is formed, processes that incorporate oxygen are avoided. More specifically, an RTA to activate implanted dopants is performed in an 0₂ free or substantially O₂ free environment.

Methodology in accordance with embodiments of the present disclosure includes forming a high-k/metal gate (HKMG) stack on a substrate; implanting dopants in active regions of the substrate; and performing a rapid thermal anneal (RTA) in an environment of nitrogen and no more than 30% oxygen.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

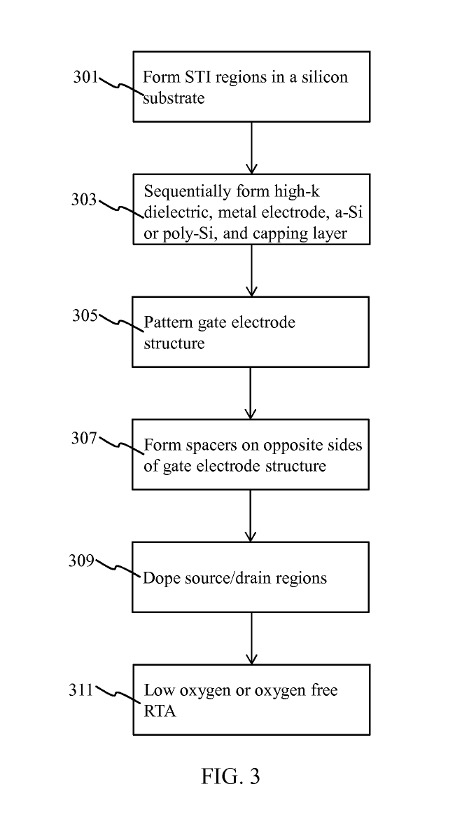

FIG. 3 is a flowchart showing a process flow, in accordance with an exemplary embodiment of the present disclosure. Adverting to step 301, the process begins with formation of STI regions in a silicon substrate, by conventional methods. The STI regions are formed between adjacent MOSFETS, such as between a PFET and an NFET, to electrically isolate them from each other.

An exemplary gate first process for forming an HKMG stack is shown in steps 303 and 305. In step 303, a high-k dielectric layer, a metal electrode layer, an a-Si or poly-Si layer, and a gate capping layer 111 are sequentially formed on the substrate. The high-k dielectric layer may, for example, be formed of hafnium oxide (HfO₂) or hafnium silicon oxynitride (HfSiON). The metal electrode may, for example, be formed of TiN. The layers are then patterned, in step 305, by conventional lithography and etching to form a gate electrode structure.

Spacers are formed on opposite sides of the gate electrode structure in step 307. Adverting to step 309, source/drain regions are then doped, using the gate electrode and spacers as a mask. For a PFET, a p-type dopant, for example boron, is employed for the deep source/drain implantation, and for an NFET, an n-type dopant, such as phosphorus or arsenic, is used for the deep source/drain implantation. Extension and halo regions may also be formed.

Adverting to step 311, after all implantation steps have been performed, the dopants are activated, for example, by an RTA. The RTA is performed in a nitrogen environment with no more than 30% oxygen. The RTA is performed at a temperature of 1035° C. to 1075° C., e.g. at 1050° C.

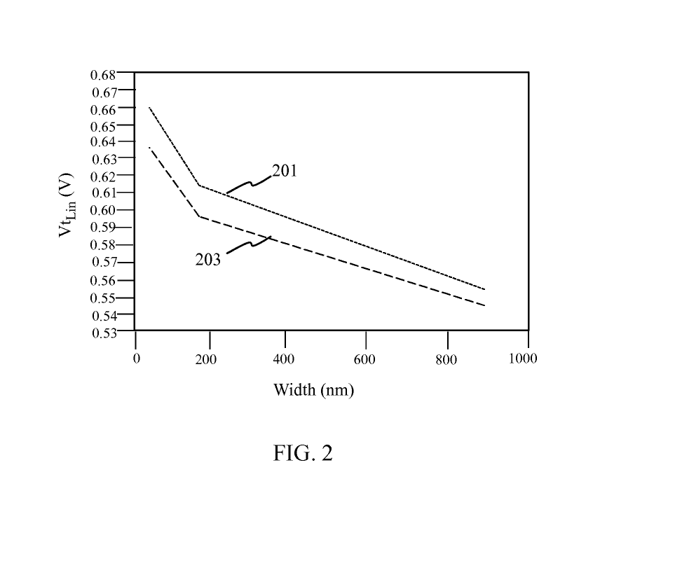

Returning to FIG. 2, graph 203 illustrates the relationship between transistor width and threshold voltage when the RTA is performed in an N₂ environment that is free from oxygen. As shown changing the RTA environment from N₂O₂ to N₂ reduces the roll-up (the difference in Vₜ between a long channel device of 900 nm and a small channel device of 72 nm) by 30 millivolts (mV). The reduction of O₂ during the RTA therefore reduces the effects of device scaling on Vₜ.

The embodiments of the present disclosure can achieve several technical effects including lower Vt_{Lin} versus width roll-up, which increases yield and device performance, particularly for NFETs, with minimal process change. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly low power, high performance semiconductor devices in 32 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a high-k/metal gate (HKMG) stack on a substrate;
implanting dopants in active regions of the substrate; and
performing a rapid thermal anneal (RTA) in an environment of nitrogen and no more than 30% oxygen.

2. The method according to claim 1, comprising performing the RTA in an oxygen free environment.

3. The method according to claim 2, comprising performing the RTA at a temperature of 1035° C. to 1075° C.

4. The method according to claim 1, comprising implanting n-type dopants in the active regions of the substrate.

5. The method according to claim 1, comprising forming the HKMG stack by:
forming a high-k dielectric layer on the substrate;
forming a metal electrode layer on the high-k dielectric layer;
forming an amorphous silicon (a-Si) or polycrystalline silicon (poly-Si) layer on the metal electrode layer; and
patterning the layers.

6. The method according to claim 5, comprising forming the high-k dielectric layer of a hafnium oxide (HfO₂) or hafnium silicon oxynitride (HfSiON).

7. The method according to claim 5, comprising patterning by lithographic etching.

8. The method according to claim 1, further comprising forming spacers on opposite sides of the HKMG stack prior to implanting dopants in the active regions of the substrate.

9. The method according to claim 1, comprising forming shallow trench isolation (STI) regions in the substrate prior to forming the HKMG stack.

10. A device comprising:
a substrate;
a high-k/metal gate (HKMG) stack on the substrate;
source/drain regions in the substrate on opposite sides of the HKMG stack;
a dopant implanted in the source/drain regions and activated with a rapid thermal anneal (RTA) in an environment of nitrogen and no more than 30% oxygen.

11. The device according to claim 10, wherein the dopant is activated with an RTA in an oxygen free environment.

12. The device according to claim 10, wherein the dopant is an n-type dopant.

13. The device according to claim 10, wherein the HKMG comprises:
a high-k dielectric layer on the substrate;
a metal electrode layer on the high-k dielectric layer; and
an amorphous silicon (a-Si) or polycrystalline silicon (poly-Si) layer on the metal electrode layer.

14. The device according to claim 10, further comprising shallow trench isolation (STI) regions in the substrate adjacent the source/drain regions.

15. The device according to claim 10, further comprising spacers at opposite sides of the HKMG stack.

16. A method comprising:
forming shallow trench isolation (STI) regions in a substrate;
forming a high-k/metal gate (HKMG) stack on the substrate between two adjacent STI regions, the HKMG stack comprising:
a high-k dielectric layer on the substrate,
a metal electrode layer on the high-k dielectric layer, and
an amorphous silicon (a-Si) or polycrystalline silicon (poly-Si) layer on the metal electrode layer;
implanting n-type dopants in source/drain regions of the substrate between the two STI regions, at opposite sides of the HKMG stack; and
performing a rapid thermal anneal (RTA) in an environment of nitrogen and no more than 30% oxygen.

17. The method according to claim 16, comprising performing the RTA in an oxygen free environment.

18. The method according to claim 16, comprising forming the high-k dielectric layer of a hafnium oxide (HfO₂) or hafnium silicon oxynitride (HfSiON).

19. The method according to claim 16, performing the RTA at a temperature of 1035° C. to 1075° C.

20. The method according to claim 16, comprising forming the HKMG stack by lithographically etching the high-k dielectric layer, the metal electrode layer, and the a-Si or poly-Si layer.
